(19) United States
(12) Patent Application Publication
(10) Pub. No.: US 2024/0413215 A1
(43) Pub. Date: Dec. 12, 2024

(54) INNER SPACER FORMATION THROUGH STIMULATION

(71) Applicant: Taiwan Semiconductor Manufacturing Co., Ltd., Hsinchu (TW)

(72) Inventors: Wei-Jen Lo, Hsinchu (TW); Syun-Ming Jang, Hsinchu (TW); Mu-Chieh Chang, Zhubei City (TW); Tze-Liang Lee, Hsinchu (TW)

(21) Appl. No.: 18/451,986

(22) Filed: Aug. 18, 2023

Related U.S. Application Data
(60) Provisional application No. 63/507,201, filed on Jun. 9, 2023.

(51) Int. Cl. H01L 29/417; H01L 29/06; H01L 29/423; H01L 29/66; H01L 29/775

(52) U.S. Cl. CPC H01L 29/41775; H01L 29/0673; H01L 29/42392; H01L 29/6653; H01L 29/66553; H01L 29/775

(57) ABSTRACT

A method includes forming a stack of layers, which includes a plurality of semiconductor nanostructures, and a plurality of sacrificial layers. The plurality of semiconductor nanostructures and the plurality of sacrificial layers are arranged alternatingly. The method further includes laterally recessing the plurality of sacrificial layers to form lateral recesses, depositing a spacer layer extending into the lateral recesses, trimming the spacer layer to form inner spacers, and performing a treatment process to reduce dielectric constant values of the inner spacers.

### PRIORITY CLAIM AND CROSS-REFERENCE

This application claims the benefit of the following provisionally filed U.S. patent application: Application No. 63/507,201, filed on Jun. 9, 2023, and entitled “Low K Material Formation by External Stimulator,” which application is hereby incorporated herein by reference.

### BACKGROUND

In the formation of Gate All Around (GAA) transistors, inner spacers are formed to separate source/drain regions from replacement gate stacks, so that in the formation of the replacement gate stacks, the inner spacers may block the etching of dummy gates. The inner spacers also have the function of reducing the leakage between the source/drain regions and the replacement gate stacks. The inner spacers are formed of dielectric materials.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 11A, 11B, 12A, 12B, 13A, 13B, 13C, 14A, 14B, and 14C illustrate the cross-sectional views of intermediate stages in the formation of a Gate-All-Around (GAA) transistor in accordance with some embodiments.

FIGS. 15-18 illustrate the cross-sectional views of intermediate stages in the formation of multi-layer inner spacers in accordance with some embodiments.

FIGS. 19-21 illustrate the cross-sectional views of intermediate stages in the formation of single-layer inner spacers in accordance with some embodiments.

FIGS. 22 and 23 illustrate the distribution profiles of the atomic percentages of some elements in accordance with some embodiments.

FIG. 24 illustrates a process flow for forming a GAA transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate All Around (GAA) transistor including inner spacers and the method of forming the same are provided. In accordance with some embodiments of the present disclosure, the inner spacers are formed by forming recesses between nanostructures, and depositing a dielectric layer, which has a relatively high dielectric constant (k value). The dielectric layer has good gap-filling ability. The dielectric layer is then etched, and the remaining portions of the dielectric layer form inner spacers. Since the dielectric layer is relatively dense and is relatively resistant to etching, the dishing of the inner spacer is reduced. A treatment process is then performed to convert the dielectric layer as a low-k dielectric layer through stimulation, so that in the resulting GAA transistor, the parasitic capacitance between source/drain regions and replacement gate stacks is reduced. The dielectric layer may have a multi-layer structure including two or more layers formed of different materials, or may be a single layer formed of a homogeneous material.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

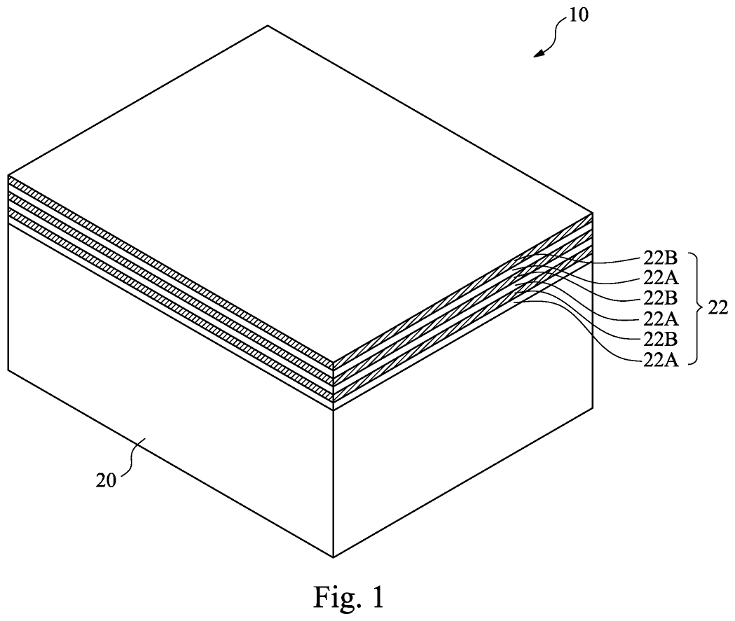

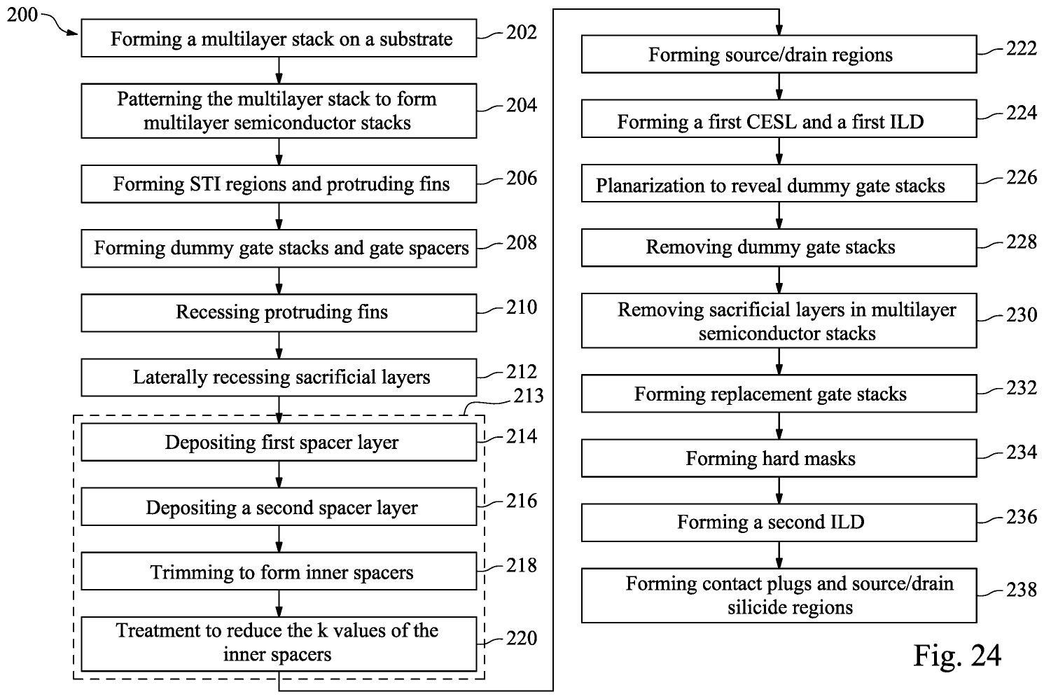

FIGS. 1-4, 5A, 5B, 6A, 6B, 7A, 7B, 8A, 8B, 9A, 9B, 10A, 10B, 11A, 11B, 12A, 12B, 13A, 13B, 13C, 14A, 14B, and 14C illustrate the cross-sectional views of intermediate stages in the formation of an GAA transistor in accordance with some embodiments of the present disclosure. The corresponding processes are also reflected schematically in the process flow shown in FIG. 24.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 as shown in FIG. 24. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22B may be formed to a second thickness in the range between about 10 Å and about 500 Å, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there are some pad oxide layer(s) and hard mask layer(s) (not shown) formed over multilayer stack 22. These layers are patterned, and are used for the subsequent patterning of multilayer stack 22.

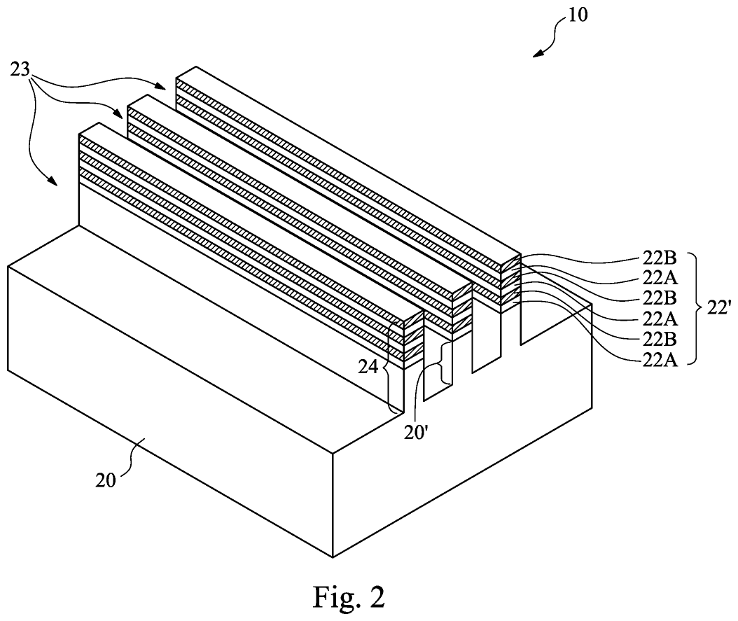

Referring to FIG. 2, multilayer stack 22 and a portion of the underlying substrate 20 are patterned in an etching process(es), so that trenches 23 are formed. The respective process is illustrated as process 204 in the process flow 200 as shown in FIG. 24. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

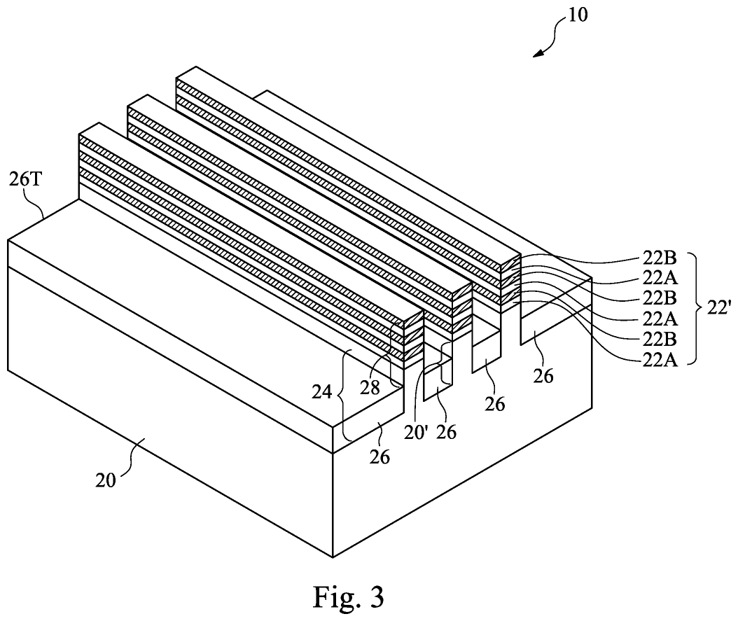

FIG. 3 illustrates the formation of isolation regions 26, which are also referred to as Shallow Trench Isolation (STI) regions throughout the description. The respective process is illustrated as process 206 in the process flow 200 as shown in FIG. 24. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

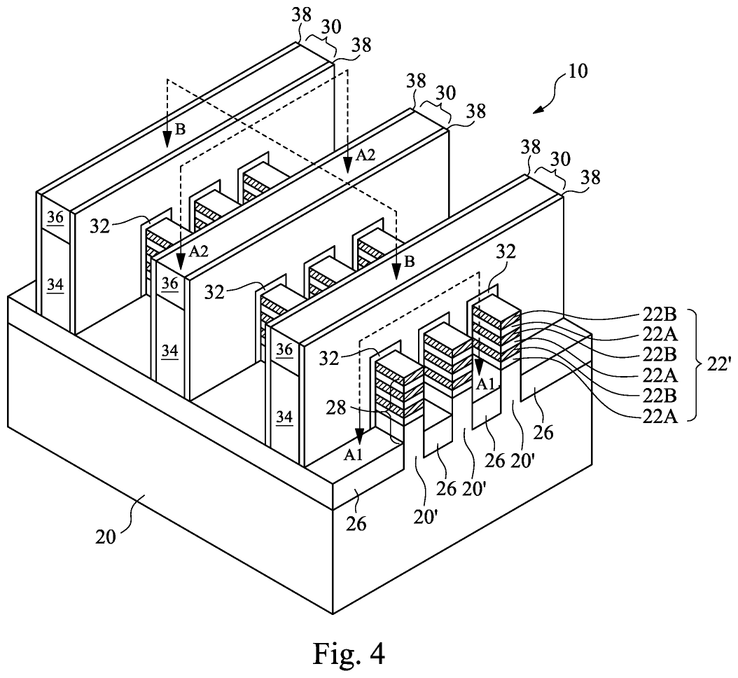

Referring to FIG. 4, dummy gate stacks 30 and gate spacers 38 are formed on the top surfaces and the sidewalls of (protruding) fins 28. The respective process is illustrated as process 208 in the process flow 200 as shown in FIG. 24. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

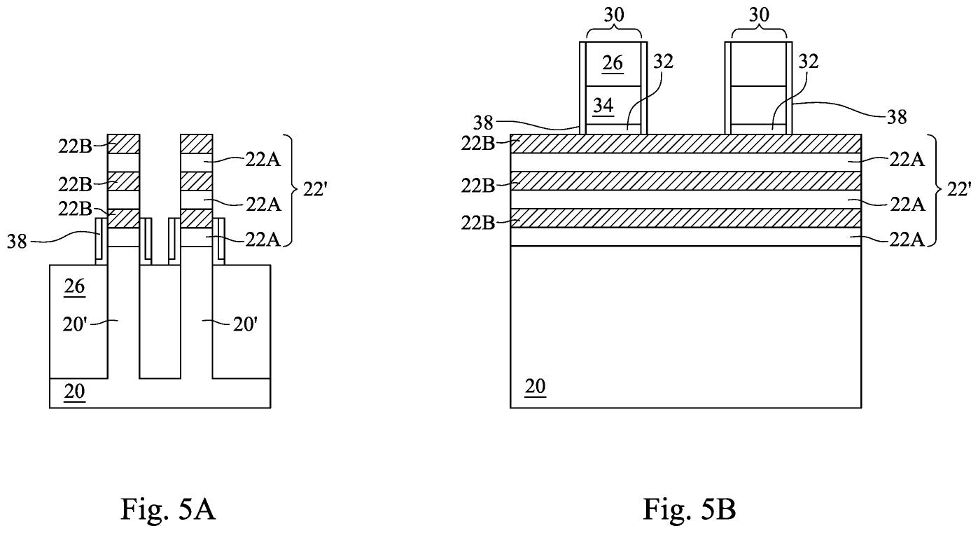

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by gate stacks 30 and gate spacers 38, and is perpendicular to the gate-length direction. In accordance with some embodiments, the formation of gate spacers 38 include depositing a conformal dielectric layer(s), and performing an anisotropic etching process to remove the horizontal portions of the conformal dielectric layers. At the same time gate spacers are left on the sidewall of the dummy gate stacks 30, the dielectric layers are also formed on the sidewalls of the protruding fins 28, and the corresponding remaining portions are also referred to as fin spacers (also marked as 38). FIG. 5B illustrates the reference cross-section B-B in FIG. 4, which reference cross-section is parallel to the lengthwise directions of protruding fins 28.

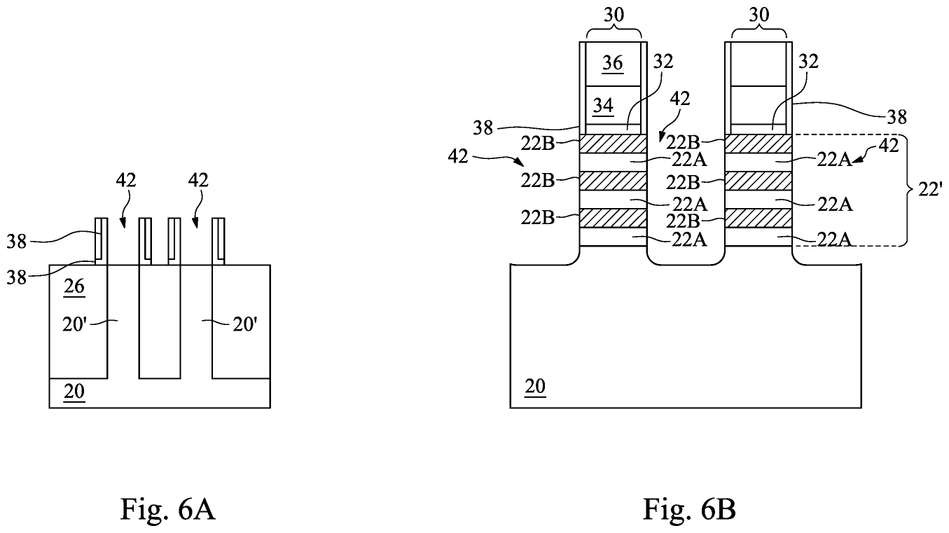

Referring to FIGS. 6A and 6B, the portions of protruding fins 28 that are not directly underlying dummy gate stacks 30 and gate spacers 38 are recessed through an etching process to form recesses 42. The respective process is illustrated as process 210 in the process flow 200 as shown in FIG. 24. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

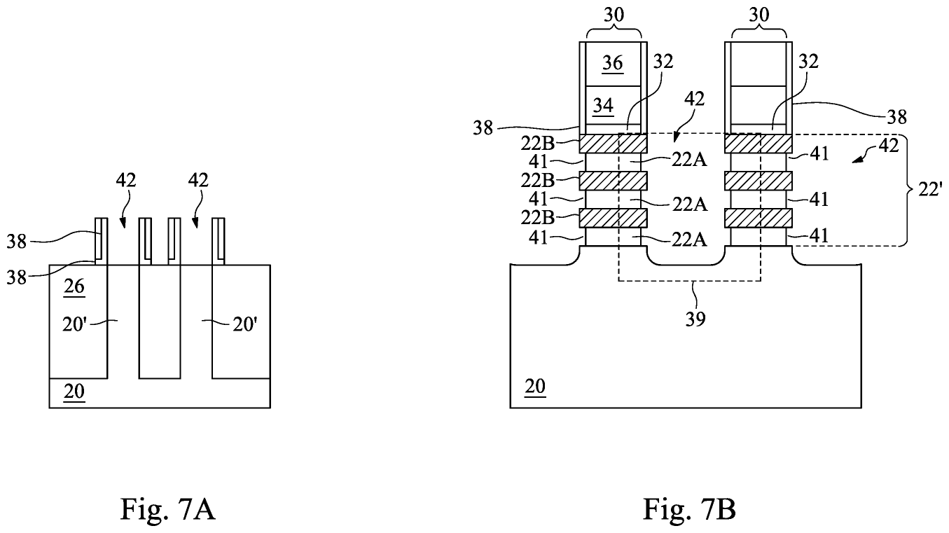

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 as shown in FIG. 24. The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like, and may be performed using any suitable process temperatures (for example, between about 400° C. and about 600° C.) and a suitable process time (for example, between about 100 seconds and about 1,000 seconds). In accordance with alternative embodiments, the lateral recessing of sacrificial semiconductor layers 22A is performed through an isotropic dry etching process or a combination of a dry etching process and a wet etching process.

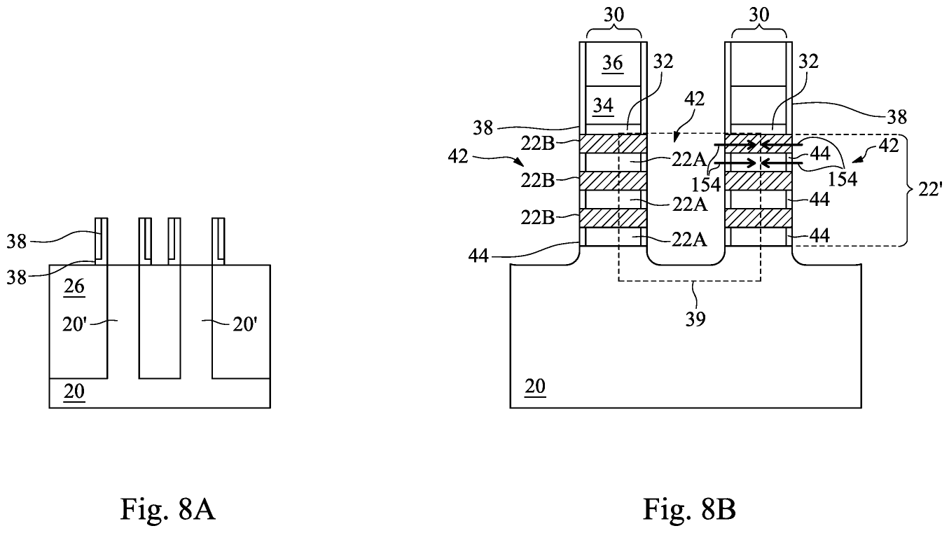

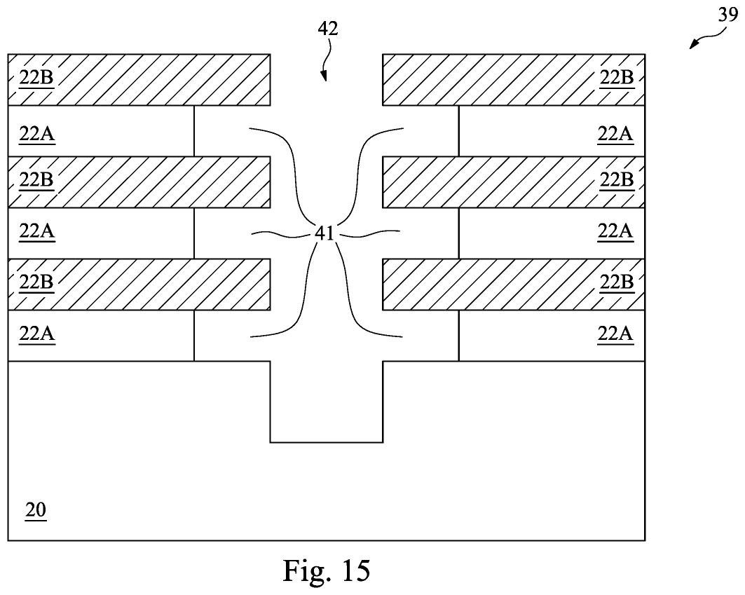

FIGS. 8A and 8B illustrate the formation of inner spacers 44. The respective process is illustrated as process 213 in the process flow 200 as shown in FIG. 24. The detailed process for forming inner spacers 44 are shown and discussed referring to FIGS. 15 through 18 or FIGS. 18 through 21. In these embodiments, inner spacers having higher k values are formed, and then converted to have lower k values through stimulation.

FIGS. 15 through 18 illustrate the magnified cross-sectional views in the formation of multi-layer inner spacers 44 in accordance with some embodiments. In these embodiments, the catalysts for the reactions that cause the reduction of k values of inner spacers 44 are embedded in one of the spacer layers. FIG. 15 illustrates a magnified view of region 39 in FIG. 7B. Sacrificial semiconductor layers 22A have been laterally recessed from the respective outer edges of nanostructures 22B, with lateral recesses 41 being underlying the respective overlying nanostructures 22B.

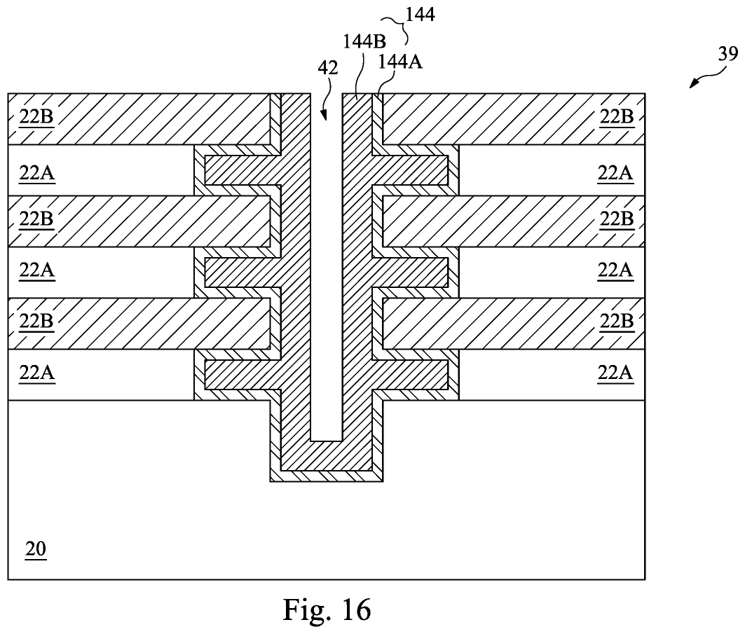

Next, referring to FIG. 16, a first spacer layer 144A, which is a dielectric layer, is deposited. The respective process is illustrated as process 214 in the process flow 200 as shown in FIG. 24. Spacer layer 144A is sometimes referred to as a catalyst layer. The deposition may be performed using a conformal deposition process such as an ALD process or a CVD process. In accordance with some embodiments, spacer layer 144A comprises SiOCN. The carbon atomic percentage in spacer layer 144A may be in the range between about 15 percent and about 65 percent. The nitrogen atomic percentage in spacer layer 144A may be in the range between about 5 percent and about 15 percent. The atomic percentages may be obtained through X-ray photoelectron spectroscopy (XPS).

In accordance with some embodiments, spacer layer 144A has a relatively high dielectric constant (k value). In accordance with some embodiments, spacer layer 144A is a high-k dielectric layer having a k value greater than about 4.0, and may be in the range between about 4.0 and about 6.0, depending on the material and the corresponding deposition process. Spacer layer 144A may also have a k value lower than about 4.0, and may be a low-k dielectric layer with a k value lower than about 3.8 or 3.5. For example, the atomic percentage of carbon and nitrogen in spacer layer 144A may be controlled to adjust the k value into a desirable range, with a higher carbon atomic percentage leading to a lower k value, and vice versa, and a higher nitrogen atomic percentage leading to a higher k value, and vice versa.

A second spacer layer 144B is then deposited. The respective process is illustrated as process 216 in the process flow 200 as shown in FIG. 24. Spacer layers 144A and 144B are collectively referred to as spacer layers 144. Spacer layer 144B may also be deposited using a conformal deposition method such as ALD, CVD, or the like. Spacer layer 144B may fully fill lateral recesses 41 (FIG. 15) in accordance with some embodiments. In accordance with some embodiments, the entire first spacer layer 144A is formed of a homogeneous material having a uniform composition, and the entire second spacer layer 144B is formed of a homogeneous material having a uniform composition.

Throughout the description, when two features are referred to as having a same composition, the two layers have same types of elements, and the atomic percentage values of the elements are also equal to each other within process variation. Otherwise, if one of the features includes an element not in the other feature, or two features have the same elements, but the atomic percentage of at least one element is different from that in the other feature, the two features are referred to as having different compositions.

Spacer layer 144B has a different composition than spacer layer 144A. For example, spacer layer 144B may comprise a Si—N-bond-comprising material such as SiON, SiN, SiOCN, SiCN, or the like. An example material of spacer layer 144B may be SiON, without carbon therein. Spacer layer 144B, when comprising carbon, may have a low carbon atomic percentage significantly lower than that in spacer layer 144A.

In accordance with some embodiments, the carbon atomic percentage C144A in spacer layer 144A may be higher than the carbon atomic percentage C144B in spacer layer 114B. For example, a difference (C144A−C144B) may be greater than about 15 percent, 20 percent, 30 percent or more. The nitrogen atomic percentage N144A in spacer layer 144A may be higher than, equal to, or lower than the nitrogen atomic percentage N144B in spacer layer 114B. In accordance with some embodiments, the carbon atomic percentage in spacer layer 144B may be in the range between about 0 percent and about 30 percent. The nitrogen atomic percentage in spacer layer 144B may be in the range between about 0 percent and about 15 percent. In accordance with some embodiments, spacer layer 144B is a high-k dielectric layer having a k value higher than about 4.0, and the k value may be in the range between about 4.0 and about 6.0, while other k values lower than about 4.0 may also be adopted. The k value of spacer layer 144B may be higher than, equal to, or lower than the k value of spacer layer 144A.

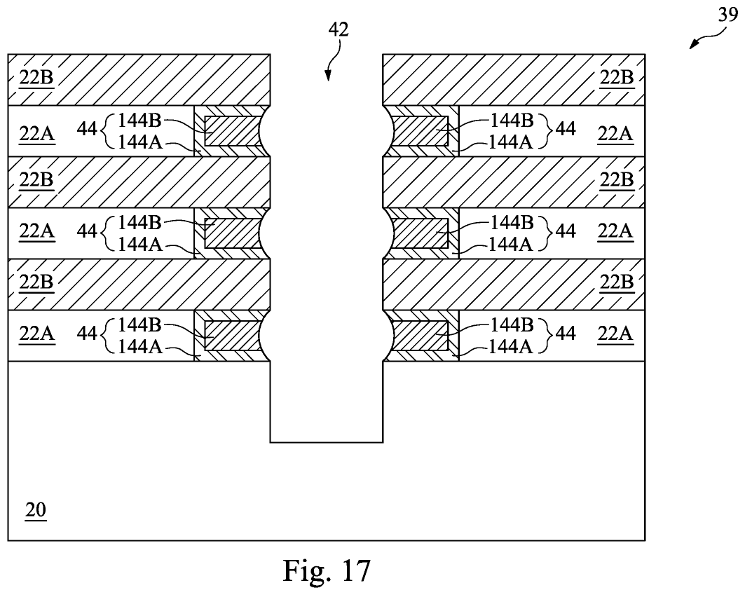

Referring to FIG. 17, a trimming process is performed to form inner spacers 44. The respective process is illustrated as process 218 in the process flow 200 shown in FIG. 24. The portions of spacer layer 144 on the sidewalls of nanostructures 22B are fully removed, so that the sidewalls of nanostructures 22B are exposed. The remaining portions of spacer layers 144A and 144B are collectively referred to as inner spacers 44.

In accordance with some embodiments, the trimming process is performed using a wet etching process. The etching chemical may include an acid solution such as a diluted HF solution, a H₂SO₄ solution, a H₃PO₄ solution, and/or the like. In accordance with alternative embodiments, the trimming process is performed using a dry etching process. The etching gas may be selected from CF₄, C₄H₆, C₄H₈, NF₃, CHF₃, CH₃F, CH₂F₂, and the like, and combinations thereof. The trimming process may also include both of a wet etching process and a dry etching process in accordance with alternative embodiments.

Inner spacer 44 may have dishing after being trimmed. Since the k value and the density of spacer layer 144B are relatively high, the dishing of inner spacers 44 is reduced. Furthermore, the k value and the density of spacer layer 144A are also relatively high, which also contributes to the reduction of dishing.

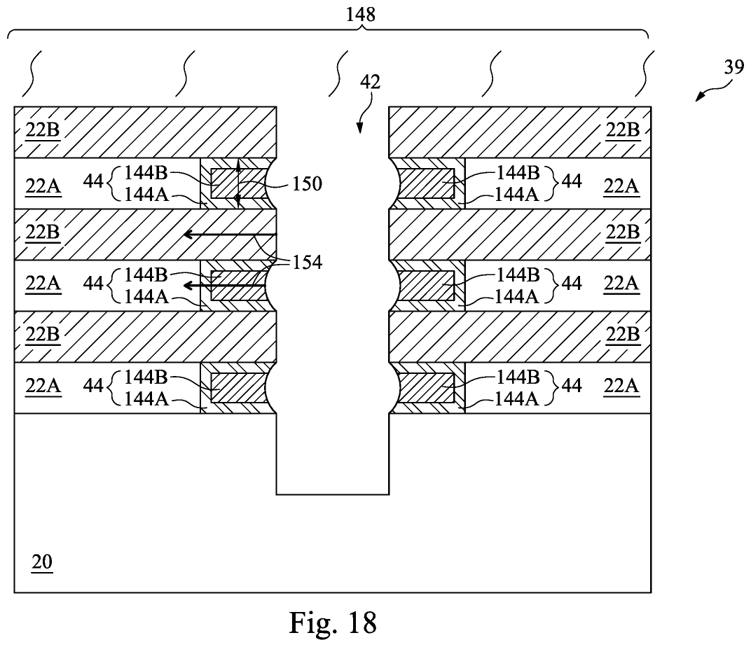

Referring to FIG. 18, treatment process 148 is performed to reduce the k value of inner spacers 44. The respective process is illustrated as process 220 in the process flow 200 as shown in FIG. 24. The treatment process 148 is hence also referred to as a k-value-reduction process. The decrease in the k value of inner spacers 44 through the treatment process 148 may be greater than about 0.5, greater than about 1.0, or greater than about 1.5. In accordance with some embodiments, the treatment process is performed with water steam (H₂O) being used as a reaction gas. For example, the water steam and/or the combination of H₂ and O₂ may be used as the reaction gas, which may contribute to the reduction of nitrogen (N), and the reduction of the inner spacers.

The resulting inner spacers 44 may thus have a low-k value, which may be lower than about 3.8 or lower than about 3.5. The treated inner spacers 44 may have a higher porosity value than before the treatment process 148. After the treatment process 148, the materials of both of dielectric layers 144A and 144B in the inner spacers 44 may comprise SiOCN or SiOCNH, although the atomic percentages of elements in dielectric layer 144A may be different from that in dielectric layer 144B.

In accordance with some embodiments, treatment process 148 is performed by applying an external stimulator. In accordance with some embodiments, the application of the stimulator includes projecting a stimulation light to introduce the energy for a reaction in spacer layer 144B. The light may have a wavelength in the range between about 200 nm and about 300 nm, while a longer wavelength or a shorter wavelength may be used. The corresponding treatment duration may be in the range between about 0.5 minutes and about 10 minutes.

In accordance with alternative embodiments, treatment process 148 is performed through a thermal treatment process by heating wafer 10 (and inner spacers 44) to introduce the energy. The thermal treatment process may be performed at a wafer temperature in the range between about 300° C. and about 800° C. The corresponding treatment duration may be in the range between about 80 minutes and about 300 minutes.

In accordance with yet alternative embodiments, treatment process 148 is performed through a plasma treatment process by generating plasma, and exposing wafer 10 (and inner spacers 44) to the generated plasma. In accordance with some embodiments, the plasma treatment may be performed using an external stimulating gas, which may comprise a nitrogen-based process gas such as N₂, NRₓH_{y} (with x>=0, y>=0, x+y=3, and R being an alkyl group), N₂O, F₂, NF₃, or the like, a fluorine-based process gas such as fluorinated hydrocarbons, or the like, or combinations thereof. The power for generating the plasma may be in the range between about 100 watts and about 7,000 watts. The corresponding treatment duration may be in the range between about 10 seconds and about 10 minutes.

During the treatment process 148, carbon diffuses from spacer layer 144A (due to its higher carbon atomic percentage) into spacer layer 144B. When spacer layer 144A has a higher nitrogen atomic percentage than spacer layer 144B, nitrogen also diffuses from spacer layer 144A into spacer layer 144B. The carbon in spacer layer 144B, under the stimulation of the provided energy, may react with water steam, and the reaction Si—N+H₂O-->S—O+NH₃ may occur. The Si—N bonds in the spacer layer 144B are turned into Si—O bonds, and ammonia (NH₃) is generated, and outgasses from inner spacers 44. Accordingly, the nitrogen atomic percentage in spacer layer 144B is reduced, and its k value is reduced.

The majority of the nitrogen, which are either originally in spacer layer 144B or diffused from spacer layer 144A will be lost due to the reaction and the outgassing. The reduction in the spacer layer 144B causes the increase in the gradient of the nitrogen atomic percent in spacer layers 144A and 144B, and more nitrogen will be diffused from spacer layer 144A into spacer layer 144B, which also causes the reduction of the k value of spacer layer 144A.

In the meantime, carbon also diffuses from spacer layer 144A into spacer layer 144B. Carbon may act as the catalyst for the reaction. Accordingly, the reaction in spacer layer 144B is accelerated. The carbon in spacer layer 144B may also be lost during the reaction, while there is still some small amount of carbon remaining in spacer layers 144A and 144B. The efficiency of the treatment process 148 is affected by the dose of the stimulators and the concentration of the catalyst (such as carbon).

In accordance with some embodiments, after the treatment process 148, both of inner spacer layers 144A and 144B (and hence inner spacers 44) may include SiCOH or SiCONH. The carbon atomic percentage in spacers layers 144A and 144B may be in the range between about 5 percent and about 30 percent. The nitrogen atomic percentage in spacers layers 144A and 144B may be in the range between about 0 percent and about 30 percent. The inner spacers 44 may have a k value smaller than about 3.5.

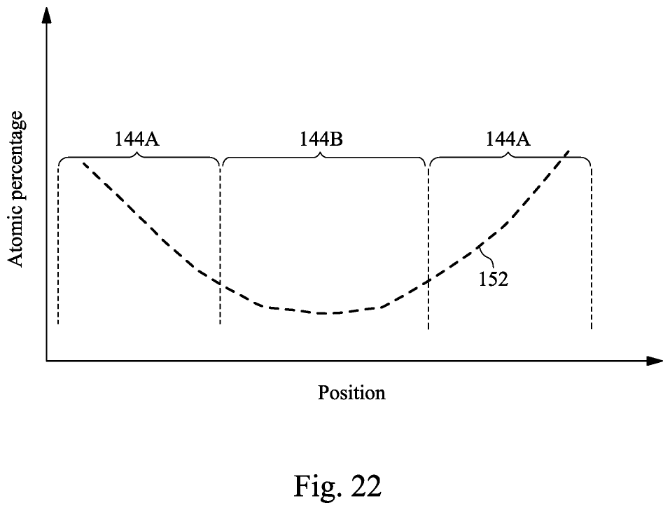

Due to the diffusion of carbon and nitrogen from spacer layer 144A into spacer layer 144B, the carbon and nitrogen may have a gradient. FIG. 22 schematically illustrates some example atomic percentages of carbon and nitrogen in spacer layers 144A and 144B, wherein the atomic percentages may be obtained at the position of the arrow 150 in FIG. 18. Line 152 in FIG. 22 illustrates that carbon and/or nitrogen may have higher atomic percentages in spacer layers 144A, and lower atomic percentages in spacer layers 144B, with a gradient being formed. The atomic percentages may be the lowest in the middle of spacer layer 144B. It is appreciated that while the atomic percentage of carbon and nitrogen may have gradual transition from spacer layer 144A into 144B, the atomic percentages of other elements such silicon may have an abrupt transition between spacer layers 144A and 144B. Accordingly, spacer layers 144A and 144B are distinguishable in the final GAA transistors.

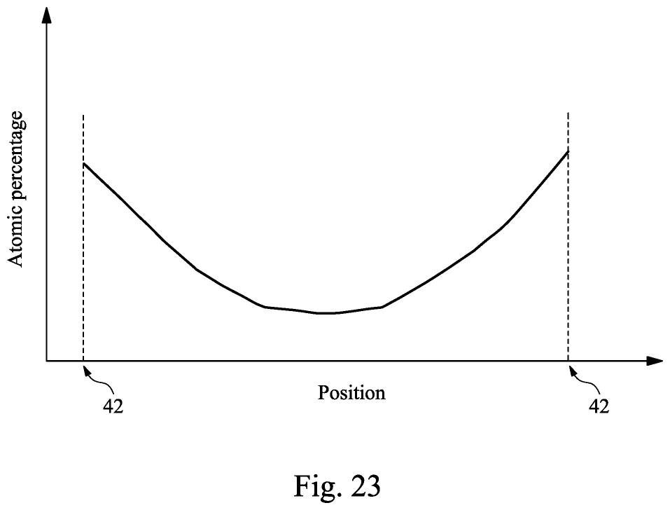

In accordance with some embodiments in which treatment process 148 comprises a plasma treatment process, the element(s) for generating the plasma and for the treatment process may be left in inner spacers 44 and nanostructures 22B as a dopant(s), and may also have a gradient. FIG. 23 illustrates an example profile of the dopants. The dopants are obtained along the directions shown by arrows 154 in FIG. 18. The dopant(s) (such as N, chlorine (Cl), hydrogen, or the like) introduced by the plasma treatment may a higher atomic percentage at the ends of inner spacers 44 and nanostructures 22B. The ends of inner spacers 44 and nanostructures 22B face and are exposed to recess 42.

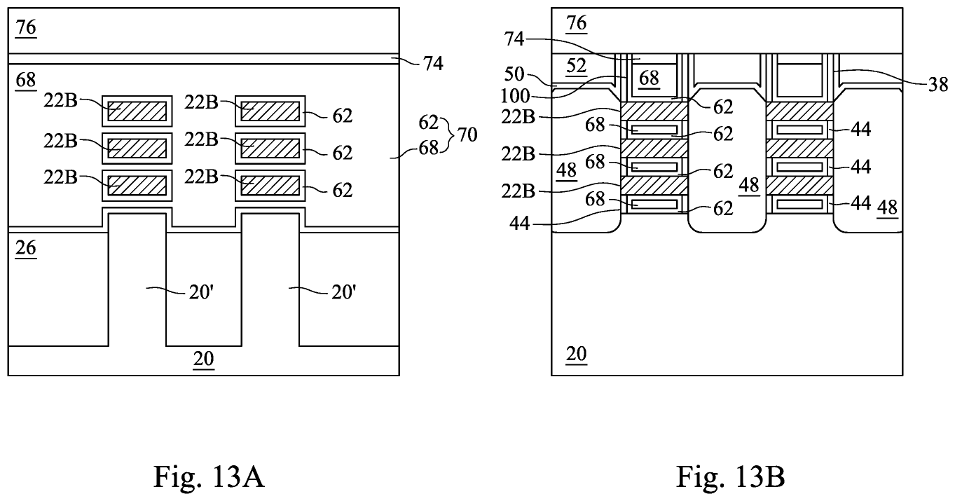

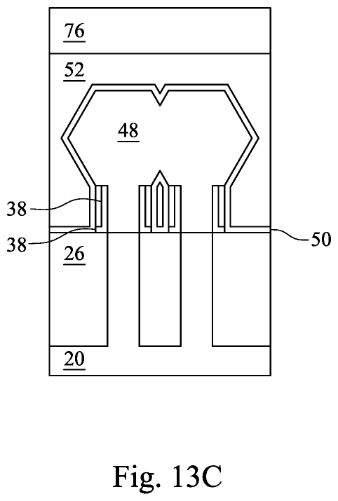

The atomic percentage values of the dopants gradually reduce going into the inner spacers 44 and nanostructures 22B. As may be realized from FIG. 8B, the dopant may diffuse from both of left-side recess 42 and right-side recess 42 toward middle. As a result, the middle part of the nanostructures 22B and sacrificial semiconductor structures 22A may have the lowest atomic percentage of the dopant, as shown in FIG. 23. The left and right ends (facing recesses 42) of sacrificial semiconductor structures 22A and nanostructures 22B, on the other hand, may have the highest atomic percentages of the dopants. The profile as shown in FIG. 23 may also be found in the final GAA transistors as shown in FIG. 13B.

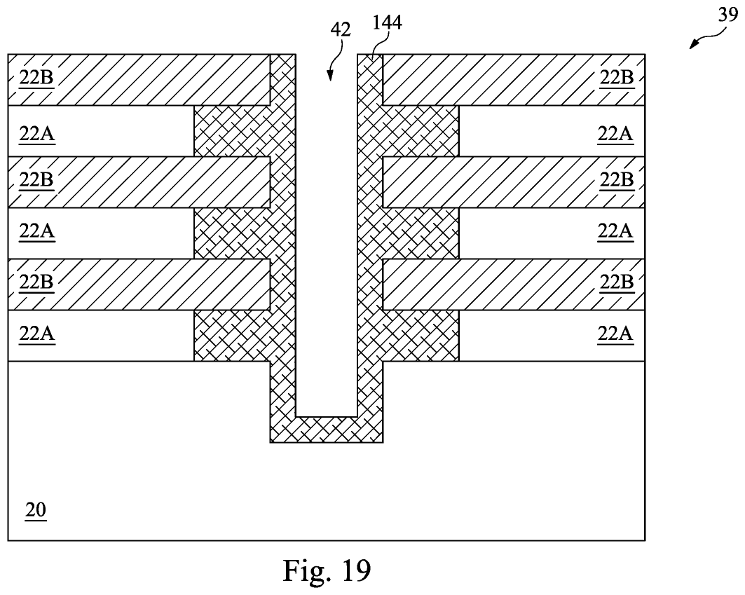

FIGS. 19-21 illustrate the magnified cross-sectional views in the formation of single-layer inner spacers 44 in accordance with alternative embodiments. In these embodiments, the catalysts for the reactions that cause the reduction of k values of inner spacers are provided by ions or radicals from a plasma treatment process, rather than embedded in the spacer layers.

Referring to FIG. 19, spacer layer 144 is deposited, and lateral recesses 41 (FIGS. 7B and 15) are fully filled. The entire spacer layer 144 may be formed of a homogeneous material. Spacer layer 144 may be deposited using a conformal deposition method such as ALD, CVD, or the like. Spacer layer 144 may comprise a Si—N-bond-comprising material such as SiON, SiN, SiOCN, SiCN, or the like. An example material of spacer layer 144 may be SiON, without carbon therein. In accordance with some embodiments, the carbon atomic percentage in spacer layer 144 may be in the range between about 0 percent and about 30 percent. The nitrogen atomic percentage in spacer layer 144 may be in the range between about 0 percent and about 15 percent. In accordance with some embodiments, spacer layer 144 is a high-k dielectric layer having a k value higher than about 4.0, and may be in the range between about 4.0 and about 6.0, while the k value of spacer layer 144 may also be between about 3.5 and about 4.0.

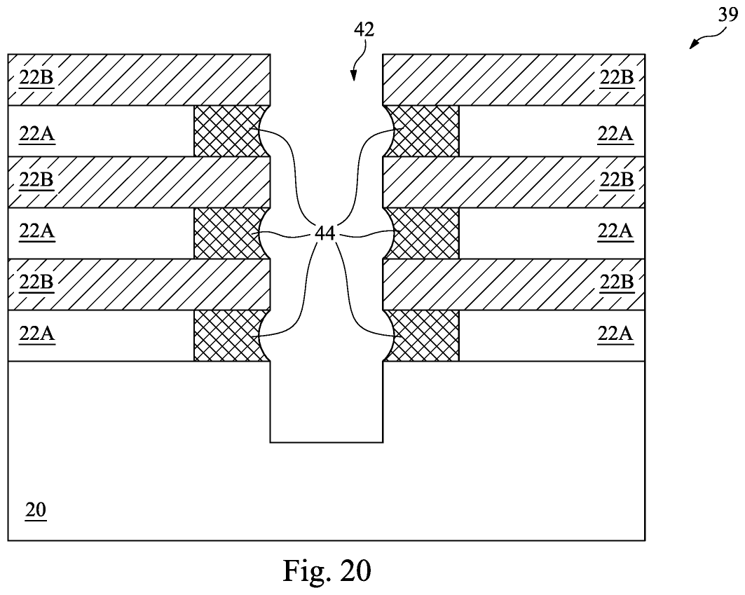

Referring to FIG. 20, a trimming process is performed, hence forming inner spacers 44. Since the k value and the density of spacer layer 144 are relatively high, the dishing of inner spacers 44 may be small.

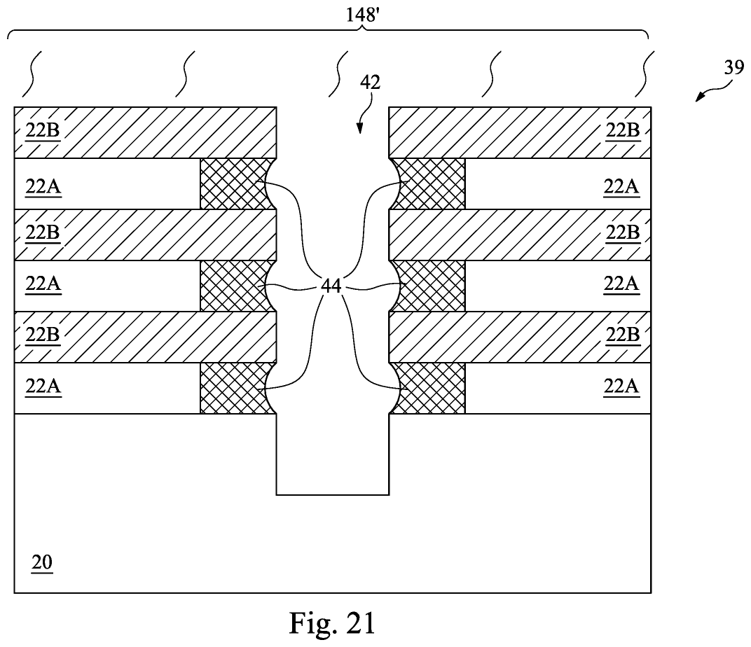

Referring to FIG. 21, treatment process 148′ is performed to reduce the k value of inner spacers 44. In accordance with some embodiments, treatment process 148′ is performed through a plasma treatment process by generating plasma, and exposing wafer 10 (and inner spacers 44) to the generated plasma. During the treatment process 148′, stimulators such as the ions and/or radicals of the process gases comprising hydrogen, nitrogen, fluorine, and/or the like may be used to cause the reaction in inner spacers 44. In accordance with some embodiments, the process for generating the plasma may comprise ICP, CCP, remote plasma, microwave plasma, and or the like. During the treatment process 148′, carbon may be provided in the plasma to be used as the catalyst, and carbon may be introduced by using a carbon-containing gas such as CO₂, lower alkanes (C<7), fluorinated hydrocarbons, or the like as a process gas. Furthermore, water steam (H₂O) and/or the combination of H₂ and O₂ may be used as the reaction gas to incur the reaction Si—N+H₂O-->S—O+NH₃, so that nitrogen may be removed from inner spacers 44.

Through the reaction, the k value of inner spacers 44 is reduced. In accordance with some embodiments, the resulting inner spacers 44 may have a low-k value, which may be lower than 3.8 or lower than about 3.5, and may have a higher porosity value than before the treatment process 148′. The decrease of the k value of inner spacers 44 due to the treatment process 148′ may be greater than about 0.2, greater than about 0.5, greater than about 1.0, or greater. The treated inner spacers 44 may comprise SiOCN or SiOCNH.

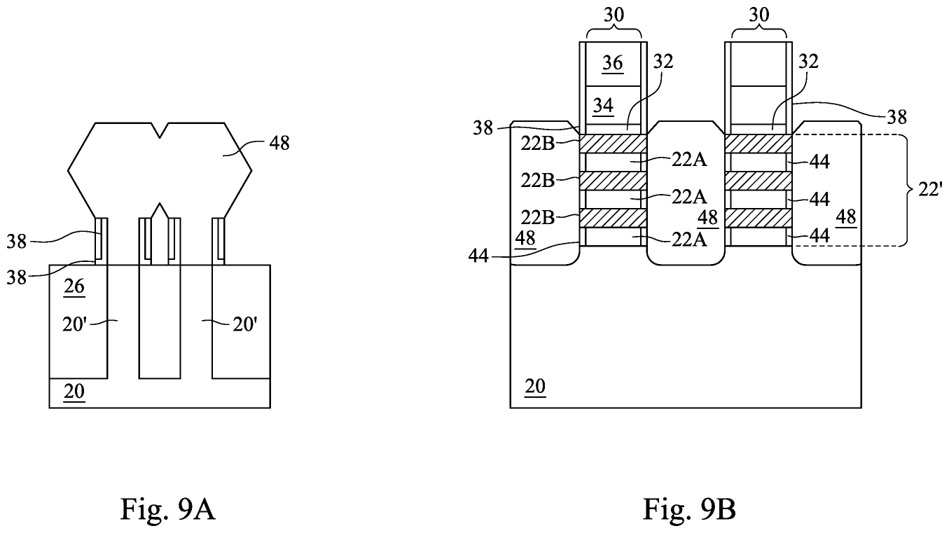

Referring to FIGS. 9A and 9B, epitaxial source/drain regions 48 are formed in recesses 42. Source/drain region(s) may refer to a source or a drain, individually or collectively dependent upon the context. The respective process is illustrated as process 222 in the process flow 200 as shown in FIG. 24. In accordance with some embodiments, the source/drain regions 48 may exert stress on the nanostructures 22B, which are used as the channels of the corresponding GAA transistors, thereby improving performance. Depending on whether the resulting transistor is a p-type transistor or an n-type transistor, a p-type or an n-type impurity may be in-situ doped with the proceeding of the epitaxy. For example, when the resulting transistor is a p-type Transistor, silicon germanium boron (SiGeB), silicon boron (SiB), or the like may be grown. Conversely, when the resulting transistor is an n-type Transistor, silicon phosphorous (SiP), silicon carbon phosphorous (SiCP), or the like may be grown.

The subsequent figure numbers may have the corresponding numbers followed by letter A, B, or C. The figure with the figure number having the letter A indicates that the corresponding figure shows a reference cross-section same as the reference cross-section A2-A2 in FIG. 4, the figure with the figure number having the letter B indicates that the corresponding figure shows a reference cross-section same as the reference cross-section B-B in FIG. 4, and the figure with the figure number having the letter C indicates that the corresponding figure shows a reference cross-section same as the reference cross-section A1-A1 in FIG. 4.

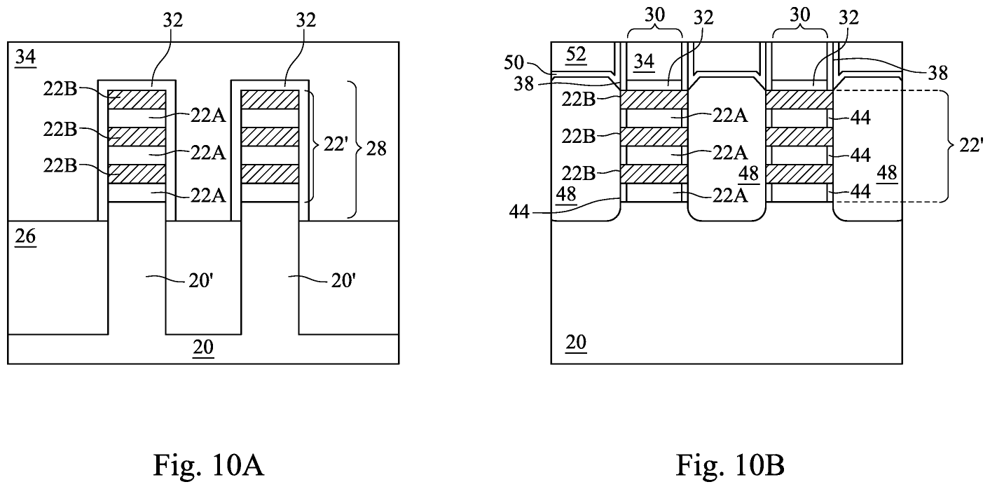

FIGS. 10A and 10B illustrate the cross-sectional views of the structure after the formation of Contact Etch Stop Layer (CESL) 50 and Inter-Layer Dielectric (ILD) 52. The respective process is illustrated as process 224 in the process flow 200 as shown in FIG. 24. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be a silicon-oxide based material formed using Tetra Ethyl Ortho Silicate (TEOS) as a precursor, Phospho-Silicate Glass (PSG), Boro-Silicate Glass (BSG), Boron-Doped Phospho-Silicate Glass (BPSG), Undoped Silicate Glass (USG), or the like.

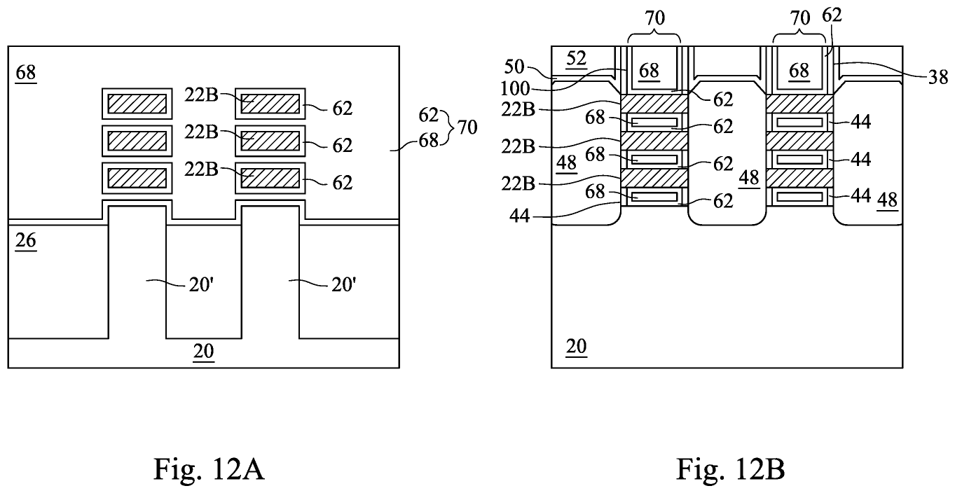

A planarization process such as a CMP process or a mechanical grinding process is performed to level the top surface of ILD 52. The respective process is illustrated as process 226 in the process flow 200 as shown in FIG. 24. In accordance with some embodiments, the planarization process may remove hard masks 36 to reveal dummy gate electrodes 34, as shown in FIG. 12A. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

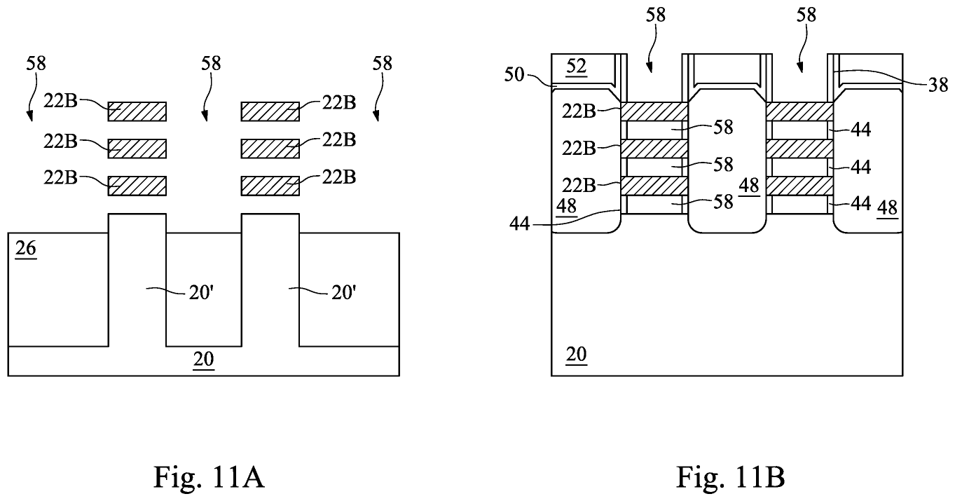

Next, dummy gate stacks 34 are removed in one or more etching processes, so that recesses 58 are formed, as shown in FIGS. 11A and 11B. The respective process is illustrated as process 228 in the process flow 200 as shown in FIG. 24. The portions of the dummy gate dielectrics 32 exposed to recesses 58 are also removed. In accordance with some embodiments, dummy gate electrodes 34 and dummy gate dielectrics 32 are removed through an isotropic dry etch process. For example, the etching process may be performed using reaction gas(es) that selectively etch dummy gate electrodes 34 at a faster rate than ILD 52. Each recess 58 exposes and/or overlies portions of multilayer stacks 22′, which include the future channel regions in subsequently completed nano-FETs. The portions of the multilayer stacks 22′, are between neighboring pairs of the epitaxial source/drain regions 48.

Sacrificial layers 22A are then removed to extend recesses 58 between nanostructures 22B. The respective process is illustrated as process 230 in the process flow 200 as shown in FIG. 24. Sacrificial layers 22A may be removed by performing an isotropic etching process such as a wet etching process using etchants which are selective to the materials of sacrificial layers 22A, while nanostructures 22B, substrate 20, STI regions 26 remain relatively un-etched as compared to sacrificial layers 22A. In accordance with some embodiments in which sacrificial layers 22A include, for example, SiGe, and nanostructures 22B include, for example, Si or SiC, tetra methyl ammonium hydroxide (TMAH), ammonium hydroxide (NH₄OH), or the like may be used to remove sacrificial layers 22A.

Referring to FIGS. 12A and 12B, replacement gate stacks 70 are formed. The respective process is illustrated as process 232 in the process flow 200 as shown in FIG. 24. In accordance with some embodiments, the replacement gate stacks 70 include gate dielectrics 62 and gate electrodes 68. Each of gate dielectrics 62 includes an interfacial layer and a high-k dielectric layer on the interfacial layer. The interfacial layer may be formed of or comprises silicon oxide, which may be deposited through a conformal deposition process such as ALD or CVD. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 are then formed. In their formation, conductive layers are first formed on the high-k dielectric layer, and fill the remaining portions of recesses 58. Gate electrodes 68 may include a metal-containing material such as TIN, TaN, TiAl, TiAlC, cobalt, ruthenium, aluminum, tungsten, combinations thereof, and/or multilayers thereof. For example, although single-layer gate electrodes 68 are illustrated in FIGS. 16A and 16B, gate electrodes 68 may comprise any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20′. After the filling of recesses 58, a planarization process such as a CMP process or a mechanical grinding process is performed to remove the excess portions of the gate dielectrics and the material of gate electrodes 68, which excess portions are over the top surface of ILD 52. Gate electrodes 68 and gate dielectrics 62 are collectively referred to as gate stacks 70 of the resulting nano-FETs.

In the processes shown in FIGS. 13A, 13B, and 13C, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52. The respective process is illustrated as process 234 in the process flow 200 as shown in FIG. 24.

As further illustrated by FIGS. 13A, 13B, and 13C, ILD 76 is deposited over ILD 52 and over gate masks 74. The respective process is illustrated as process 236 in the process flow 200 as shown in FIG. 24. An etch stop layer (not shown) may be, or may not be, deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

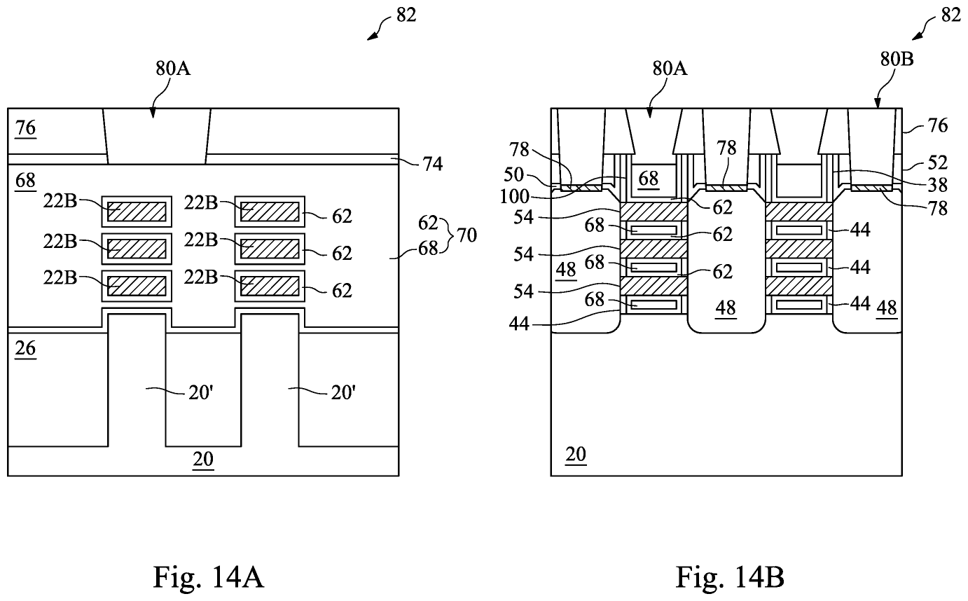

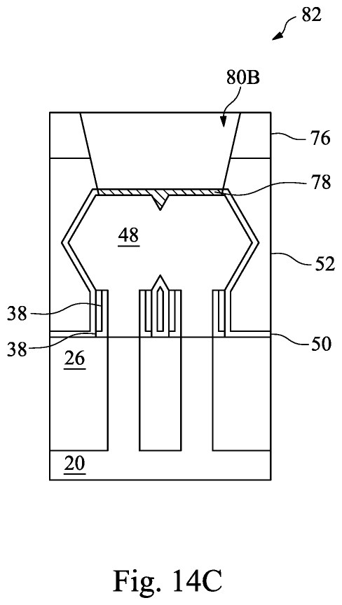

In FIGS. 14A, 14B, and 14C, ILD 76, ILD 52, CESL 50, and gate masks 74 are etched to form recesses, followed by the formation of contact plugs 80A and 80B for electrically connecting to gate stacks 70 and epitaxial source/drain regions 48, respectively. The respective process is illustrated as process 238 in the process flow 200 as shown in FIG. 24. Source/drain silicide layers 78 are also formed. The materials and the formation processes are not discussed in detail herein. Nano-FET 82 is thus formed.

The embodiments of the present disclosure have some advantageous features. By forming a spacer layer(s) with a relatively high k value and etching the spacer layer to form inner spacers, the dishing of the inner spacers is reduced. The spacer layer(s) also have good gap-filling capability, so that no void will be formed in the inner spacers. By converting the inner spacers having the higher k values to have lower k values, the parasitic capacitance between the source/drain regions and the gate electrodes is reduced. The treatment process involves a small amount of external stimulators, and hence the damage to the structure is minimized.

In accordance with some embodiments of the present disclosure, a method comprises forming a stack of layers comprising a plurality of semiconductor nanostructures; and a plurality of sacrificial layers, wherein the plurality of semiconductor nanostructures and the plurality of sacrificial layers are arranged alternatingly; laterally recessing the plurality of sacrificial layers to form lateral recesses; depositing a spacer layer extending into the lateral recesses; trimming the spacer layer to form inner spacers; and performing a treatment process to reduce dielectric constant values of the inner spacers. In an embodiment, the depositing the spacer layer comprises depositing a first spacer layer having a first carbon atomic percentage; and depositing a second spacer layer on the first spacer layer, wherein the second spacer layer has a second carbon atomic percentage lower than the first carbon atomic percentage.

In an embodiment, the treatment process comprises projecting light on the inner spacers. In an embodiment, the treatment process comprises a thermal treatment process. In an embodiment, the treatment process is performed with water steam being used as a process gas. In an embodiment, the treatment process results in dielectric constant values of both the first spacer layer and the second spacer layer to be reduced. In an embodiment, the treatment process comprising a plasma treatment process.

In an embodiment, the plasma treatment process is performed by generating plasma from a process, and the process gas comprises nitrogen or fluorine. In an embodiment, the treatment process is performed after the spacer layer is trimmed to form the inner spacers. In an embodiment, before the spacer layer is trimmed, the spacer layer is a high-k dielectric layer, and wherein after the treatment process, the inner spacers comprise low-k dielectric materials. In an embodiment, the spacer layer comprises SiON, and the inner spacers comprise SiOCNH. In an embodiment, at a time after the treatment process, the inner spacers have lower carbon and nitrogen atomic percentages than the spacer layer.

In accordance with some embodiments of the present disclosure, a structure comprises a first semiconductor layer; a second semiconductor layer overlapping the first semiconductor layer; a source/drain region contacting an end of each of the first semiconductor layer and the second semiconductor layer; a gate stack, wherein a portion of the gate stack is between the first semiconductor layer and the second semiconductor layer; and a dielectric inner spacer contacting a sidewall of the portion of the gate stack, wherein the dielectric inner spacer comprises a first portion comprising a first dielectric material, wherein the first portion contacts the first semiconductor layer and the second semiconductor layer; and an second portion spaced apart from the first semiconductor layer and the second semiconductor layer by the first portion, wherein the second portion comprises a second dielectric material different from the first dielectric material.

In an embodiment, the first portion has a higher carbon atomic percentage than the second portion, and wherein from the first portion to a center of the second portion, carbon atomic percentages reduce gradually. In an embodiment, the first portion has a higher nitrogen atomic percentage than the second portion, and wherein from the first portion to a center of the second portion, nitrogen atomic percentages reduce gradually. In an embodiment, the first semiconductor layer comprises fluorine, and the source/drain region contacts the first semiconductor layer to form an interface, and wherein from the interface to a center portion of the first semiconductor layer, atomic percentage of the fluorine reduces gradually.

In an embodiment, the first semiconductor layer is between the source/drain region and an additional source/drain region, wherein the center portion is in middle between the source/drain region and the additional source/drain region, and wherein the center portion of the first semiconductor layer has a lowest fluorine atomic percentage among the first semiconductor layer.

In accordance with some embodiments of the present disclosure, a structure comprises a semiconductor layer; a gate stack underlying the semiconductor layer; an inner spacer underlying the gate stack, wherein both of the gate stack and the inner spacer are in contact with a bottom surface of the semiconductor layer, and the inner spacer comprises an outer portion comprising a first dielectric material; and an inner portion comprising a second dielectric material different from the first dielectric material; and a source/drain region contacting both of the outer portion and the inner portion. In an embodiment, both of the inner portion and the outer portion of the inner spacer comprises SiOCNH. In an embodiment, both of the inner portion and the outer portion of the inner spacer comprise low-k dielectric materials.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a stack of layers comprising:
a plurality of semiconductor nanostructures; and
a plurality of sacrificial layers, wherein the plurality of semiconductor nanostructures and the plurality of sacrificial layers are arranged alternatingly;
laterally recessing the plurality of sacrificial layers to form lateral recesses;
depositing a spacer layer extending into the lateral recesses;
trimming the spacer layer to form inner spacers; and
performing a treatment process to reduce dielectric constant values of the inner spacers.

2. The method of claim 1, wherein the depositing the spacer layer comprises:
depositing a first spacer layer having a first carbon atomic percentage; and
depositing a second spacer layer on the first spacer layer, wherein the second spacer layer has a second carbon atomic percentage lower than the first carbon atomic percentage.

3. The method of claim 2, wherein the treatment process comprises projecting light on the inner spacers.

4. The method of claim 2, wherein the treatment process comprises a thermal treatment process.

5. The method of claim 2, wherein the treatment process is performed with water steam being used as a process gas.

6. The method of claim 2, wherein the treatment process results in dielectric constant values of both the first spacer layer and the second spacer layer to be reduced.

7. The method of claim 1, wherein the treatment process comprising a plasma treatment process.

8. The method of claim 7, wherein the plasma treatment process is performed by generating plasma from a process gas, and the process gas comprises nitrogen or fluorine.

9. The method of claim 1, wherein the treatment process is performed after the spacer layer is trimmed to form the inner spacers.

10. The method of claim 1, wherein before the spacer layer is trimmed, the spacer layer is a high-k dielectric layer, and wherein after the treatment process, the inner spacers comprise low-k dielectric materials.

11. The method of claim 10, wherein the spacer layer comprises SiON, and the inner spacers comprise SiOCNH.

12. The method of claim 11, wherein at a time after the treatment process, the inner spacers have lower carbon and nitrogen atomic percentages than the spacer layer.

13. A structure comprising:
a first semiconductor layer;
a second semiconductor layer overlapping the first semiconductor layer;
a source/drain region contacting an end of each of the first semiconductor layer and the second semiconductor layer;
a gate stack, wherein a portion of the gate stack is between the first semiconductor layer and the second semiconductor layer; and
a dielectric inner spacer contacting a sidewall of the portion of the gate stack, wherein the dielectric inner spacer comprises:
a first portion comprising a first dielectric material, wherein the first portion contacts the first semiconductor layer and the second semiconductor layer; and
an second portion spaced apart from the first semiconductor layer and the second semiconductor layer by the first portion, wherein the second portion comprises a second dielectric material different from the first dielectric material.

14. The structure of claim 13, wherein the first portion has a higher carbon atomic percentage than the second portion, and wherein from the first portion to a center of the second portion, carbon atomic percentages reduce gradually.

15. The structure of claim 13, wherein the first portion has a higher nitrogen atomic percentage than the second portion, and wherein from the first portion to a center of the second portion, nitrogen atomic percentages reduce gradually.

16. The structure of claim 13, wherein the first semiconductor layer comprises fluorine, and the source/drain region contacts the first semiconductor layer to form an interface, and wherein from the interface to a center portion of the first semiconductor layer, atomic percentage of the fluorine reduces gradually.

17. The structure of claim 16, wherein the first semiconductor layer is between the source/drain region and an additional source/drain region, wherein the center portion is in middle between the source/drain region and the additional source/drain region, and wherein the center portion of the first semiconductor layer has a lowest fluorine atomic percentage among the first semiconductor layer.

18. A structure comprising:
a semiconductor layer;
a gate stack underlying the semiconductor layer;
an inner spacer underlying the gate stack, wherein both of the gate stack and the inner spacer are in contact with a bottom surface of the semiconductor layer, and the inner spacer comprises:
an outer portion comprising a first dielectric material; and
an inner portion comprising a second dielectric material different from the first dielectric material; and
a source/drain region contacting both of the outer portion and the inner portion.

19. The structure of claim 18, wherein both of the inner portion and the outer portion of the inner spacer comprise SiOCNH.

20. The structure of claim 18, wherein both of the inner portion and the outer portion of the inner spacer comprise low-k dielectric materials.
